(19) United States
(12) Patent Application Publication
(10) Pub. No.: US 2012/0074406 A1
(43) Pub. Date: Mar. 29, 2012

(54) PHOTOSENSOR

(75) Inventors: Terunori Saitou, Mobara (JP); Toshio Miyazawa, Chiba (JP); Atsushi Hasegawa, Togane (JP); Takeshi Yonekura, Chiba (JP)

(73) Assignees: Panasonic Liquid Crystal Display Co., Ltd.; Hitachi Displays, Ltd.

(21) Appl. No.: 13/242,117

(22) Filed: Sep. 23, 2011

(30) Foreign Application Priority Data
Sep. 28, 2010 (JP) 2010-216375

(51) Int. Cl. H01L 31/0376; H01L 31/12

(52) U.S. Cl. 257/53; 257/E31.047

(57) ABSTRACT

A photosensor includes a photosensor array in which plural photosensor pixels are arranged in a matrix form and a backlight arranged below the photosensor array. The photosensor array includes a surface light-shielding film (for example, Al film), and the surface light-shielding film includes an incident hole through which light from an opposite side to the backlight is incident on the respective photosensor pixels, and a passage hole which is provided around the incident hole and irradiates the opposite side with irradiation light from the backlight.

### CROSS-REFERENCE TO RELATED APPLICATION

The present application claims priority from Japanese application JP2010-216375 filed on Sep. 28, 2010, the content of which is hereby incorporated by reference into this application.

### BACKGROUND OF THE INVENTION

1. Field of the Invention

The present invention relates to a photosensor, and particularly to a vein authentication sensor in which a light source is arranged below a photosensor array.

2. Description of the Related Art

In a related art vein authentication sensor, an infrared light-emitting diode (700 to 900 nm) is used as a light source, and a CCD and a lens for obtaining a focused image are mounted at a light-receiving side. A structure of the related art vein authentication sensor is shown in FIG. 12 to FIG. 14.

FIG. 12 shows a structure in which an infrared light-emitting diode 8 is provided at an upper side of a finger 1, FIG. 13 shows a structure in which infrared light-emitting diodes 8 are provided at right and left sides of the finger 1, and FIG. 14 shows a structure in which infrared light-emitting diodes 8 are provided in right and left oblique directions relative to the finger 1.

In the related art vein authentication sensor, infrared light is incident from above, or laterally or obliquely on the hand or the finger 1 placed above a photosensor array 2 as a light-receiving element, a lens 3 condenses the light emerging from the hand or the finger 1, and the condensed light is incident on the photosensor array 2. The vein authentication sensor authenticates the image of the vein projected on the photosensor array 2 by this.

JP 2010-39594A and JP 2010-97483A disclose the related art vein authentication sensor.

In the related art vein authentication sensor, since the infrared light is incident on the inside of the hand or the finger, and the image of the vein is projected, a certain amount of light is required. Thus, the contrast of the image of the vein becomes low, and the sensitivity must be raised by image processing. Further, in the structure, since the lens 3 is required to be used in addition to the photosensor array 2, it is necessary to secure a distance between the infrared light-emitting diode 8 and the hand or the finger, and between the hand or the finger and the photosensor array 2. Accordingly, there is a problem that the photosensor array itself is difficult to be made compact.

### SUMMARY OF THE INVENTION

The invention is made to solve the problem of the related art, and an object thereof is to provide a photosensor that is designed to be compact.

The above and other objects and novel features of the invention will be clarified in the description of the specification together with the attached drawings.

Among the inventions disclosed in this application, outlines of typical ones will be briefly described as follows.

(1) A photosensor includes a photosensor array in which plural photosensor pixels are arranged in a matrix form and a backlight arranged below the photosensor array. The photosensor array includes a surface light-shielding film (for example, Al film). The surface light-shielding film includes an incident hole through which light from an opposite side to the backlight is incident on the respective photosensor pixels, and a passage hole which is provided around the incident hole and irradiates the opposite side with irradiation light from the backlight.

(2) In (1), the backlight includes a light guide plate and a light source arranged on a side surface of the light guide plate.

(3) In (2), a reflecting film is provided on a surface of the light guide plate at an opposite side to the photosensor array.

(4) In (1), the backlight includes a light guide plate and a light source arranged on a surface of the light guide plate at an opposite side to the photosensor array.

(5) In (2) or (4), a plurality of optical sheets are arranged on a surface of the light guide plate at a side of the photosensor array.

(6) In any one of (1) to (5), each of the photosensor pixels includes a lower electrode made of a metal film, an amorphous silicon film provided on the lower electrode, an n-type amorphous silicon film provided on the amorphous silicon film, and an upper electrode (for example, ITO) provided on the n-type amorphous silicon film.

(7) In (6), a flattening film (for example, an organic insulating film) is provided between the respective photosensor pixels.

(8) In (6) or (7), the surface light-shielding film is arranged between the flattening film and the upper electrode, and a passage hole for irradiating the opposite side with the light from the backlight is formed also in the lower electrode at a place corresponding to the passage hole of the surface light-shielding film.

(9) In any one of (6) to (8), an insulating film is provided between the lower electrode and the amorphous silicon film. The insulating film includes a hole in an area corresponding to each of the photosensor pixels, and the lower electrode and the amorphous silicon film are electrically connected to each other in the hole formed in the insulating film.

(10) In any one of (6) to (9), the lower electrode is formed on a transparent substrate.

(11) In any one of (6) to (10), a surface protecting layer is provided on the upper electrode.

Among the inventions disclosed in this application, effects of typical ones will be briefly described as follows.

According to the invention, a photosensor that can be designed to be compact can be provided.

### BRIEF DESCRIPTION OF THE DRAWINGS

FIG. 1 is a schematic view for explaining a structure of a photosensor of an embodiment of the invention.

FIG. 2 is an exploded perspective view showing a schematic structure of the photosensor of the embodiment when an edge light type backlight is adopted as a backlight shown in FIG. 1.

FIG. 3 is an exploded perspective view showing a schematic structure of the photosensor of the embodiment when a direct under type backlight is adopted as a backlight shown in FIG. 1.

FIGS. 4A to 4I are views showing examples of a position where an infrared light passage hole is provided and the shape of the hole in the photosensor of the embodiment.

FIG. 5 is a plan view of a photosensor array shown in FIG. 1.

FIG. 6 is a sectional view showing a sectional structure taken along a cut-line A-A′ shown in FIG. 5.

FIG. 7 is a view for explaining an electrode structure of the photosensor array shown in FIG. 1.

FIG. 8 is a circuit view showing an equivalent circuit of a photosensor pixel shown in FIG. 5 to FIG. 7.

FIG. 9 is a circuit view showing a circuit structure of the photosensor array shown in FIG. 5 to FIG. 7.

FIG. 10 is a timing view for explaining a driving method of the photosensor array shown in FIG. 9.

FIGS. 11A to 11C are views showing a use example of the photosensor of the embodiment.

FIG. 12 is a view for explaining an example of a related art vein authentication sensor.

FIG. 13 is a view for explaining another example of a related art vein authentication sensor.

FIG. 14 is a view for explaining another example of a related art vein authentication sensor.

### DETAILED DESCRIPTION OF THE INVENTION

Hereinafter, embodiments of the invention will be described in detail with reference to the drawings. Incidentally, in all the drawings for explaining the embodiments, components having the same function are denoted by the same reference numeral and their repetitive explanation is omitted. Besides, the following description of the embodiments is not for limiting the interpretation of the claims of the invention.

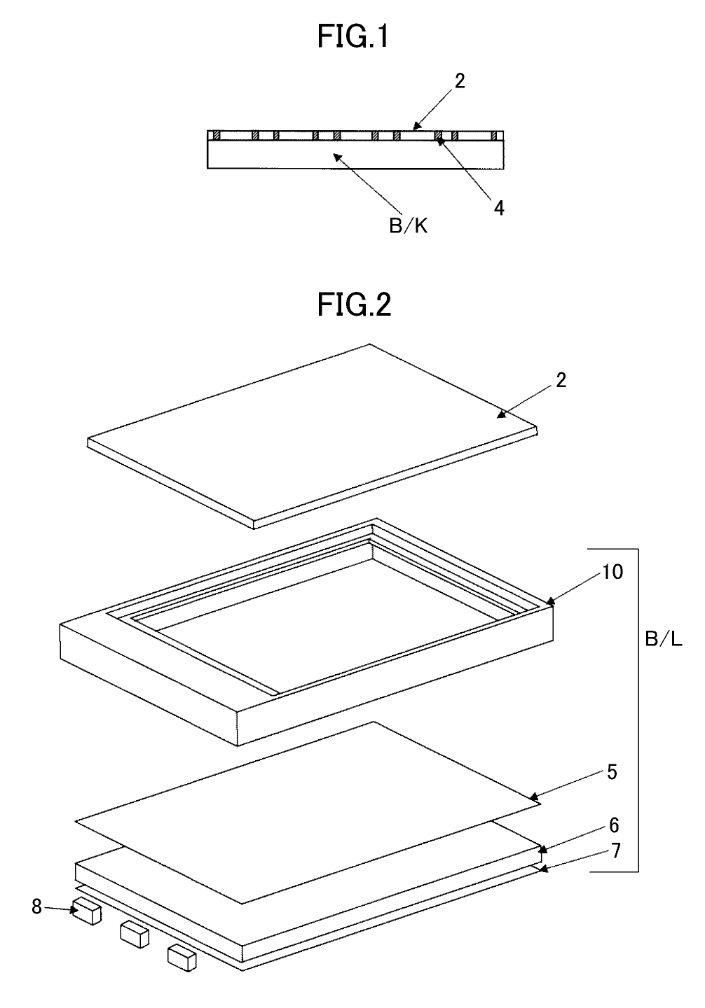

FIG. 1 is a schematic view for explaining a structure of a photosensor of an embodiment of the invention. In FIG. 1, reference numeral 2 denotes a photosensor array, and B/K denotes a backlight. As shown in FIG. 1, the photosensor of the embodiment includes the photosensor array 2 and the backlight (B/L) arranged below the photosensor array 2 like a liquid crystal display panel. The backlight irradiates infrared light to a hand or a finger as a subject from the back surface of the photosensor array 2, and images the surface of or a vein existing slightly inside the hand or the finger onto the photosensor array 2. For that purpose, an infrared light passage hole 4 is formed in the photosensor array 2.

In this embodiment, as a structure of the backlight for irradiating the infrared light to the hand or the finger from the back surface of the photosensor array 2, like the backlight of the liquid crystal display panel, there are two kinds of backlights, that is, an edge light type backlight and a direct under type backlight.

FIG. 2 is an exploded perspective view showing a schematic structure of the photosensor of the embodiment when an edge light type backlight is adopted as the backlight (B/L) shown in FIG. 1.

In the photosensor shown in FIG. 2, the backlight (B/L) includes a light guide plate 6 having a substantially rectangular shape, an infrared light-emitting diode (light source) 8 arranged on a side surface (incident surface) of the light guide plate 6, a reflecting sheet 7 arranged on a lower surface (surface at an opposite side to the photosensor array 2) side of the light guide plate 6, an optical sheet group 5 arranged on an upper surface (surface at a side of the photosensor array 2) of the light guide plate 6, and a resin mold frame 10. The optical sheet group 5 includes, for example, a lower diffusion sheet, two lens sheets and an upper diffusion sheet. Incidentally, the optical sheet group 5 can be deleted.

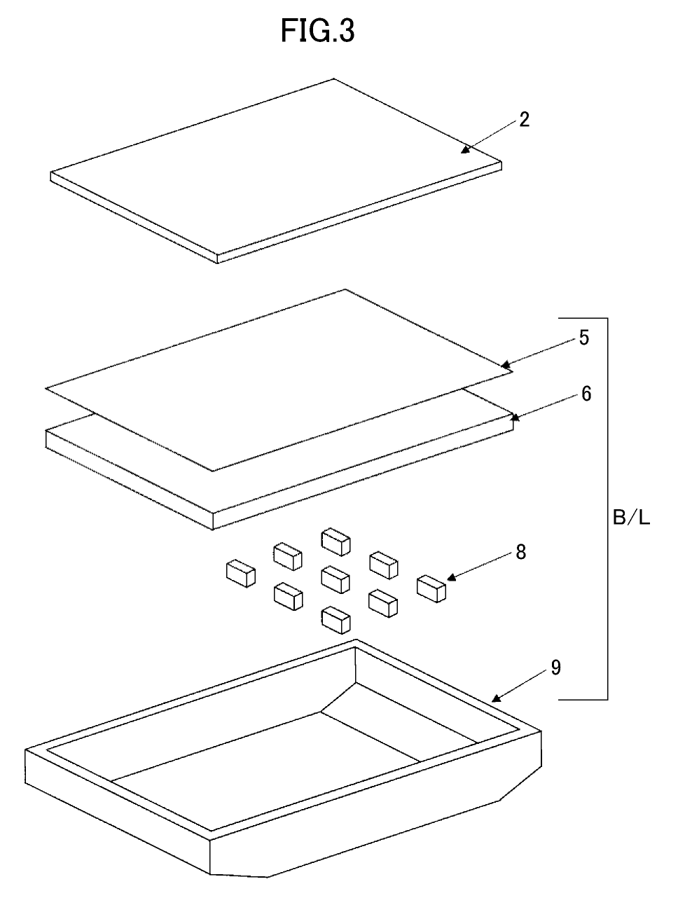

FIG. 3 is an exploded perspective view showing a schematic structure of the photosensor of the embodiment when a direct under type backlight is adopted as the backlight (B/L) shown in FIG. 1.

In the photosensor shown in FIG. 3, the backlight (B/L) includes a light guide plate 6 having a substantially rectangular shape, an infrared light-emitting diode (light source) 8 arranged on a lower surface (surface at an opposite side to the photosensor array 2) side of the light guide plate 6, an optical sheet group 5 arranged on an upper surface (surface at a side of the photosensor array 2) of the light guide plate 6, a resin mold frame 10, and a case 9 of the backlight arranged below the infrared light-emitting diode 8. Here, as the light source, nine infrared light-emitting diodes of 3 rows by 3 columns are arranged. The case 9 of the backlight includes a reflecting plate at the inside. The optical sheet group 5 includes, for example, a lower diffusion sheet, two lens sheets and an upper diffusion sheet. Incidentally, the optical sheet group 5 can be deleted.

In the structure shown in FIG. 2 and FIG. 3, the infrared light irradiated from the infrared light-emitting diode 8 is converted into uniform light by the light guide plate 6 (or the light guide plate 6 and the optical sheet group 5), and is irradiated from the infrared light passage hole 4 formed in the photosensor array 2. The uniform infrared light irradiated from the infrared light passage hole 4 is incident on the hand or the finger placed above the photosensor array 2. The incident light is reflected by the surface or a portion where a vein exists, and the reflected light is incident on respective photosensor pixels included in the photosensor array 2, and is converted into a video signal.

The position where the infrared light passage hole 4 is provided and the shape of the hole are required to be suitably set according to the size of each of the photosensor pixels of the photosensor array 2, the display size and the like. The position and the structure are desirably such that the light of the infrared light-emitting diode 8 is not directly incident on each of the photosensor pixels of the photosensor array 2, but is incident on each of the photosensor pixels of the photosensor array 2 after reflected by the hand or the finger.

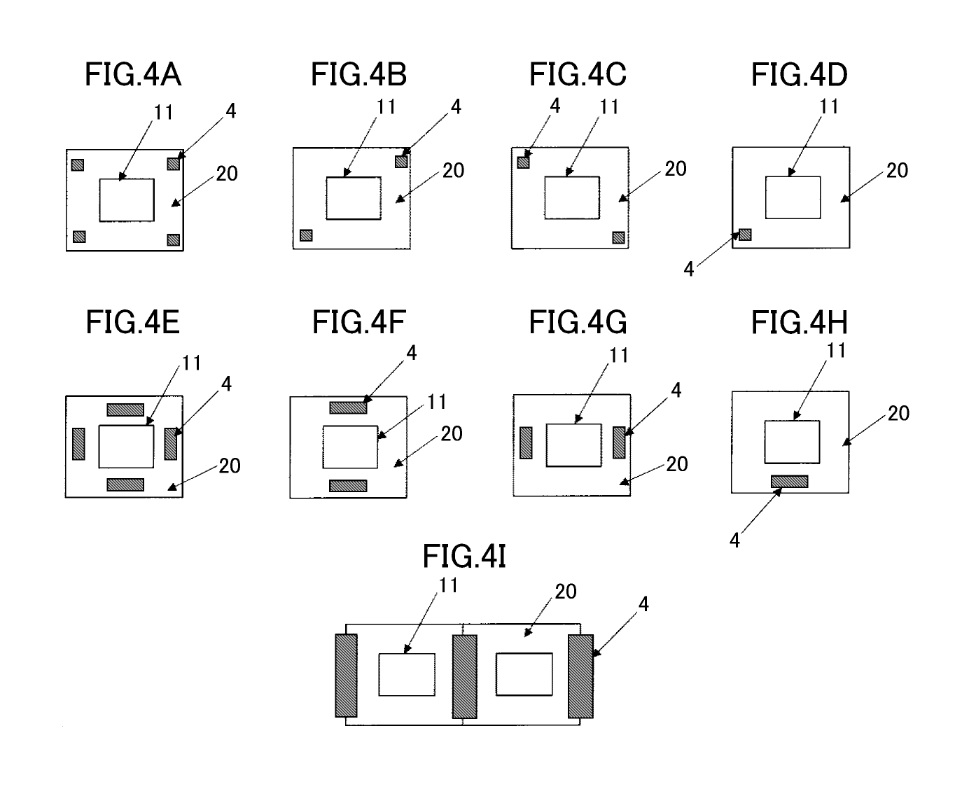

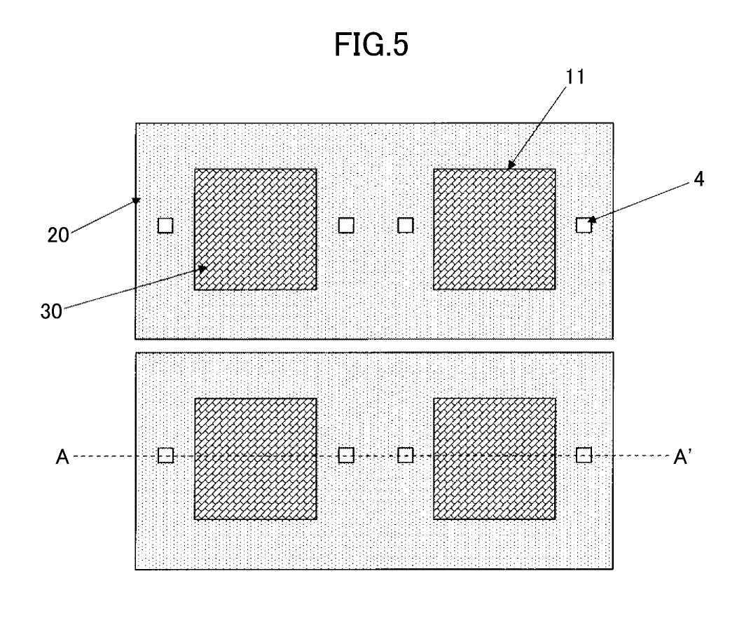

FIGS. 4A to 4I show examples of the position where the infrared light passage hole 4 is provided and the shape of the hole. In FIGS. 4A to 4I, a surface light-shielding film 20 is provided with an incident hole 11 and the infrared light passage hole 4. The infrared light is incident on a photosensor pixel PX from the incident hole 11. Incidentally, the surface light-shielding film 20 will be described later.

In FIG. 4A, as the infrared light passage hole 4, a square hole through which the infrared light passes is provided at a position of each of peripheries of four corners of the incident hole 11 in the surface light-shielding film 20.

In FIGS. 4B and 4C, as the infrared light passage hole 4, a square hole through which the infrared light passes is provided at a position of each of peripheries of two opposite corners of the incident hole 11 in the surface light-shielding film 20.

In FIG. 4D, as the infrared light passage hole 4, a square hole through which the infrared light passes is provided at a position of a periphery of one corner of the incident hole 11 in the surface light-shielding film 20.

In FIG. 4E, as the infrared light passage hole 4, a rectangular hole through which the infrared light passes is provided at a position of each of peripheries of four sides of the incident hole 11 in the surface light-shielding film 20.

In FIG. 4F, as the infrared light passage hole 4, a rectangular hole through which the infrared light passes is provided at a position of each of peripheries of upper and lower two sides of the incident hole 11 in the surface light-shielding film 20.

In FIG. 4G, as the infrared light passage hole 4, a rectangular hole through which the infrared light passes is provided at a position of each of peripheries of right and left two sides of the incident hole 11 in the surface light-shielding film 20.

In FIG. 4H, as the infrared light passage hole 4, a rectangular hole through which the infrared light passes is provided at a position of a periphery of one side of the incident hole 11 in the surface light-shielding film 20.

In FIG. 4I, as the infrared light passage hole 4, a rectangular hole through which the infrared light passes is provided between two adjacent photosensor pixels PX.

Hereinafter, an example of a structure of the photosensor array 2 shown in FIG. 1 will be described with reference to FIG. 5 to FIG. 7.

FIG. 5 is a plan view of the photosensor array 2 shown in FIG. 1, and is a view in which the photosensor array 2 shown in FIG. 1 is seen from above.

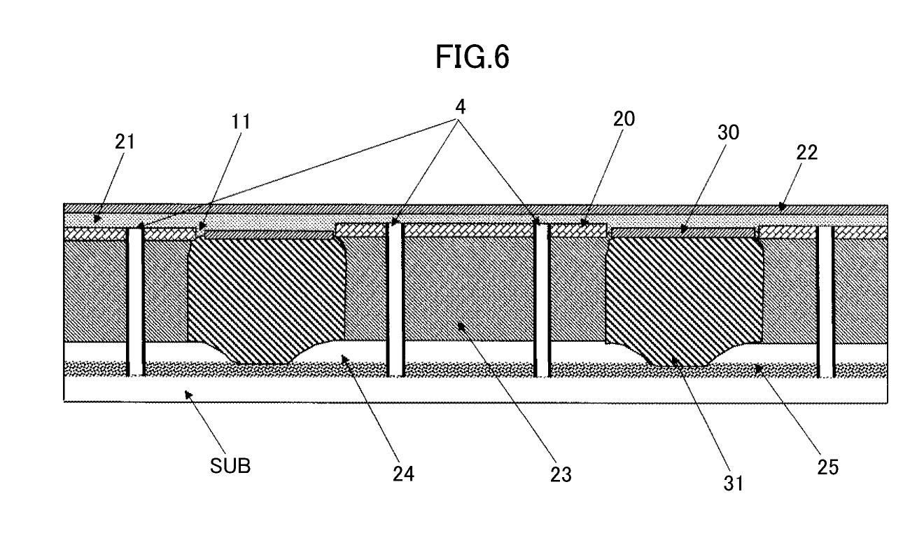

FIG. 6 is a sectional view showing a sectional structure taken along a cut-line A-A′ shown in FIG. 5.

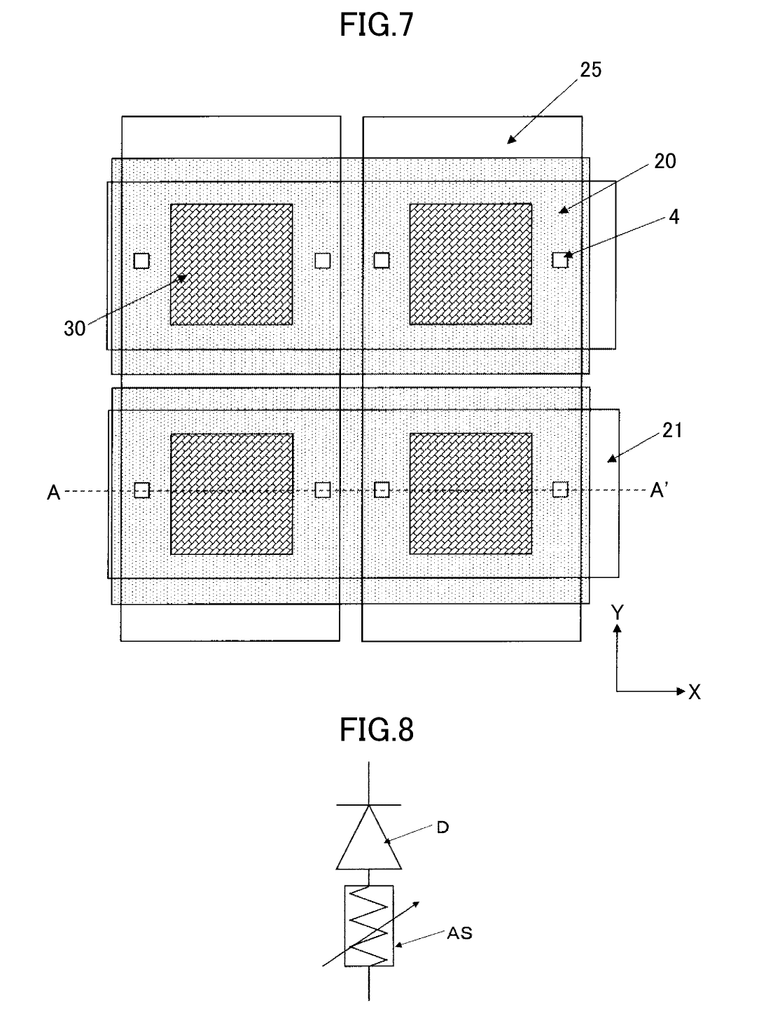

FIG. 7 is a view for explaining an electrode structure of the photosensor array 2 shown in FIG. 1.

Incidentally, although FIG. 5 and FIG. 7 show only 2×2, i.e., 4, photosensor pixels PX, in an actual photosensor array 2, for example, 100×150 photosensor pixels PX are provided.

In the photosensor array 2 shown in FIG. 5 to FIG. 7, the photosensor pixel PX includes an amorphous silicon film (a-Si) and an n-type amorphous silicon film (n+ a-Si) doped with phosphorus.

As shown in FIG. 6 and FIG. 7, the photosensor pixel PX includes a lower electrode 25, an amorphous silicon film (a-Si) 31 laminated on the lower electrode 25, an n-type amorphous silicon film (n+a-Si) 30 laminated on the amorphous silicon film (a-Si) 31 and doped with phosphorus, and an upper electrode 21 arranged on the n-type amorphous silicon film (n+a-Si) 30 doped with phosphorus.

That is, in this embodiment, the n-type amorphous silicon film (n+a-Si) 30 doped with phosphorus and the amorphous silicon film (a-Si) 31 are sandwiched between the upper electrode 21 and the lower electrode 25.

Here, the upper electrode 21 and the lower electrode 25 are respectively preferably such that an ohmic contact with the amorphous silicon film (a-Si) 31 and the n-type amorphous silicon film (n+a-Si) 30 doped with phosphorus are realized, or an ohmic contact is realized in a forward bias direction described later. Besides, since the photosensor is intended to be used, the electrode at the light incident side is required to allow light having a desired wavelength to pass through. For example, the upper electrode 21 is made of ITO (Indium Tin Oxide), and the lower electrode 25 is made of MoW/Al—Si/MoW.

The lower electrode 25 is formed on a transparent insulating substrate (for example, a glass substrate) (SUB). Further, an insulating film 24 made of silicon oxide (SiO) is formed on the lower electrode 25. A hole is formed in the insulating film 24, and the lower electrode 25 and the amorphous silicon film (a-Si) 31 are connected (ohmic contact) through the hole formed in the insulating film 24. Incidentally, the lower electrode 25 is used also as aback surface light-shielding film to prevent the infrared light irradiated from the backlight (B/L) from being directly incident on the photosensor pixel.

An organic flattening film 23 made of photo-curing resin is provided between the respective photosensor pixels PX. In other words, each of the photosensor pixels PX is arranged in the hole formed in the organic flattening film 23.

The surface light-shielding film 20 made of Al or the like is formed on the organic flattening film 23. The surface light-shielding film 20 prevents that for example, unnecessary infrared light is obliquely incident on the amorphous silicon film (a-Si) 31 of the photosensor pixel PX and noise is superimposed on sensor output detected by the photosensor pixel PX. As shown in FIG. 6, the surface light-shielding film 20 is provided between the upper electrode 21 and the organic flattening film 23.

As shown in FIG. 6, the infrared light passage hole 4 is formed so as to pass through the lower electrode 25, the insulating film 24, the organic flattening film 23, and the surface light-shielding film 20. Incidentally, when the organic flattening film 23 and the insulating film 24 are made of a material which allows the infrared light to pass through, the infrared light passage hole 4 is not required to be formed in the organic flattening film 23 and the insulating film 24.

Further, a surface protecting layer 22 made of silicon nitride (SiN) is formed on the upper electrode 21 of each of the photosensor pixels PX.

As shown in FIG. 7, the lower electrode 25 extends in, for example, a Y-direction of FIG. 7, and the upper electrode 21 and the surface light-shielding film 20 extend in, for example, an X-direction of FIG. 7. The photosensor pixel PX is formed at an intersection portion of the lower electrode 25 and the upper electrode 21.

FIG. 8 is a circuit view showing an equivalent circuit of the photosensor pixel PX shown in FIG. 5 to FIG. 7.

As indicated by a diode D of FIG. 8, since the n-type amorphous silicon film (n+ a-Si) 30 doped with phosphorus is an n-type semiconductor higher in impurity concentration than the amorphous silicon film (a-Si) 31, the contact surface between the n-type amorphous silicon film (n+ a-Si) 30 doped with phosphorus and the amorphous silicon film (a-Si) 31 indicates a diode characteristic in which the side of the amorphous silicon film (a-Si) 31 is an anode, and the side of the n-type amorphous silicon film (n+ a-Si) 30 doped with phosphorus is a cathode. Besides, as indicated by AS of FIG. 8, the amorphous silicon film (a-Si) 31 constitutes a light dependent variable resistance element.

The n-type amorphous silicon film (n+ a-Si) doped with phosphorus is laminated on the amorphous silicon film (a-Si), so that a photocurrent amplified by the diode including the n-type amorphous silicon film (n+ a-Si) doped with phosphorus and the amorphous silicon film (a-Si) can be obtained.

According to an experiment, the structure in which the n-type amorphous silicon film (n+ a-Si) doped with phosphorus is laminated on the amorphous silicon film (a-Si) shown in FIG. 5 to FIG. 7 has a current amplification effect approximately 10000 times higher than the structure including only the amorphous silicon film (a-Si).

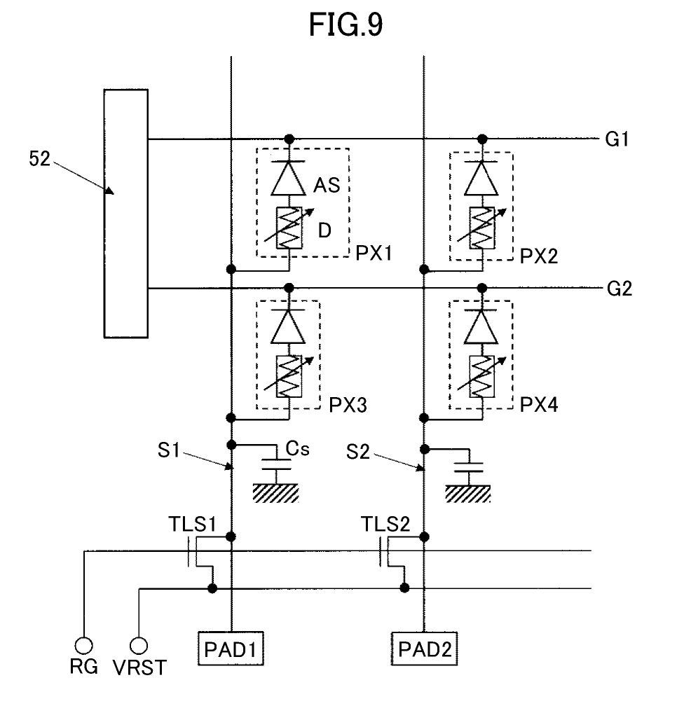

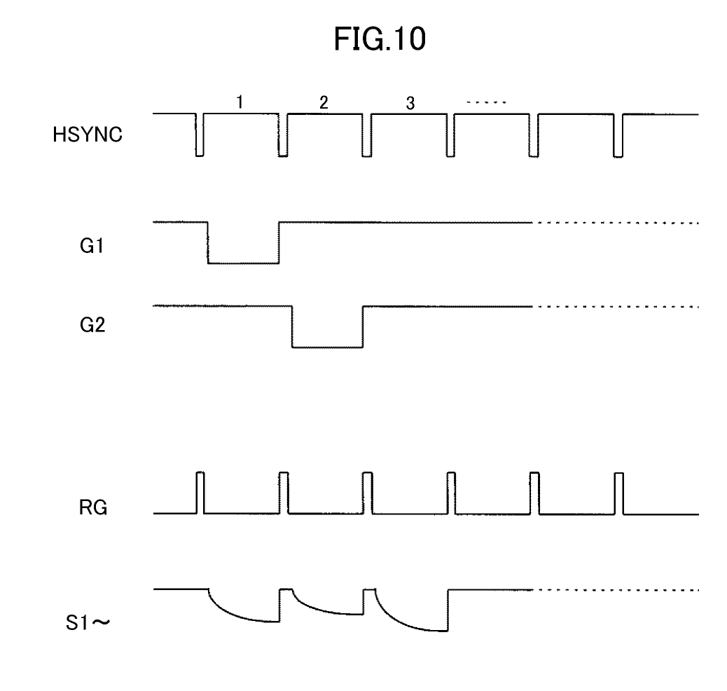

Hereinafter, the photosensor array 2 shown in FIG. 5 to FIG. 7 will be described with reference to FIG. 9 and FIG. 10.

FIG. 9 is a circuit view showing a circuit structure of the photosensor array 2 shown in FIG. 5 to FIG. 7. Incidentally, although FIG. 9 shows only four photosensor pixels of PX1 to PX4, actually, for example, 100×150 photosensor pixels are arranged.

The upper electrode 21 of the photosensor pixel of each row among the photosensor pixels (PX1 to PX4) arranged in a matrix form is connected to one of plural scanning lines (G1, G2, Accordingly, the cathode of the diode D of each of the photosensor pixels (PX1 to PX4) is connected to the scanning line (G1, G2, . . . ).

The respective scanning lines (G1, G2, . . . ) are connected to a shift register 52, and the shift register 52 sequentially supplies a selection scanning voltage of Low level (hereinafter referred to as L level) to the scanning lines (G1, G2, . . . ) every horizontal scanning period.

Besides, the lower electrode 25 of the photosensor pixel of each column among the photosensor pixels (PX1 to PX4) arranged in a matrix form is connected to one of plural read lines (S1, S2, . . . ). A voltage change of the read line (S1, S2, . . . ) in one horizontal scanning period is outputted as a signal voltage from a bonding pad (PAD 1, PAD 2, . . . ) to an external signal processing circuit (not shown).

The shift register 52 is a circuit mounted in a semiconductor chip, and is arranged on the substrate on which the photosensor array is formed. Alternatively, the shift register 52 is formed of a circuit provided on a photosensor array substrate, such as a glass substrate, and including a thin film transistor in which a semiconductor layer is made of a polysilicon film.

FIG. 10 is a timing view for explaining a driving method of the photosensor array 2 shown in FIG. 9. Hereinafter, the driving method of the photosensor array 2 shown in FIG. 5 to FIG. 7 will be described with reference to FIG. 10. Incidentally, in FIG. 10, it is assumed that the respective photosensor pixel rows are sequentially scanned from above to below by the shift register 52, that is, in FIG. 10, a voltage of L level is sequentially applied to the gate line G in ascending order of number.

First, in a blanking period of one horizontal scanning period HSYNC, a signal RG becomes High level (hereinafter referred to as H level), and a reset transistor TLS is turned ON. By this, the respective read lines (S1, S2, . . . ) are reset, and the respective read lines (S1, S2, . . . ) are made to have a specific potential (for example, 3V). In the period in which the signal RG is the H level, the respective scanning lines (G1, G2, . . . ) are H level (for example, 3 V).

Next, when the signal RG becomes L level, the voltage level of the scanning line G1 becomes Low level (hereinafter referred to as L level, for example, ground potential of 0 V), and the voltage level of the other scanning line becomes H level. By this, the diode D, the cathode of which is connected to the scanning line G1, is placed in an ON state, and the diode D, the cathode of which is connected to a scanning line other than the scanning line G1, is placed in an OFF state. Thus, the photosensor pixels of PX1 and PX2 are placed in the ON state, and the photosensor pixels of PX3 and PX4 are placed in the OFF state.

Light is incident on the photosensor pixels of PX1 and PX2, and the resistance value of the light dependent variable resistance element AS of the photosensor pixel changes according to the incident light. By this, current flowing from the read line (S1, S2, . . . ) to the scanning line G1 changes, and the potential (specifically the potential of stray capacitance Cs connected to each read line) of each read line (S1, S2, . . . ) is reduced.

This voltage change is read as a signal voltage of each read line (S1, S2, . . . ). This state is shown as a read line waveform S1˜ of FIG. 10.

The same process is performed also on a scanning line other than G1, and a signal voltage is taken in.

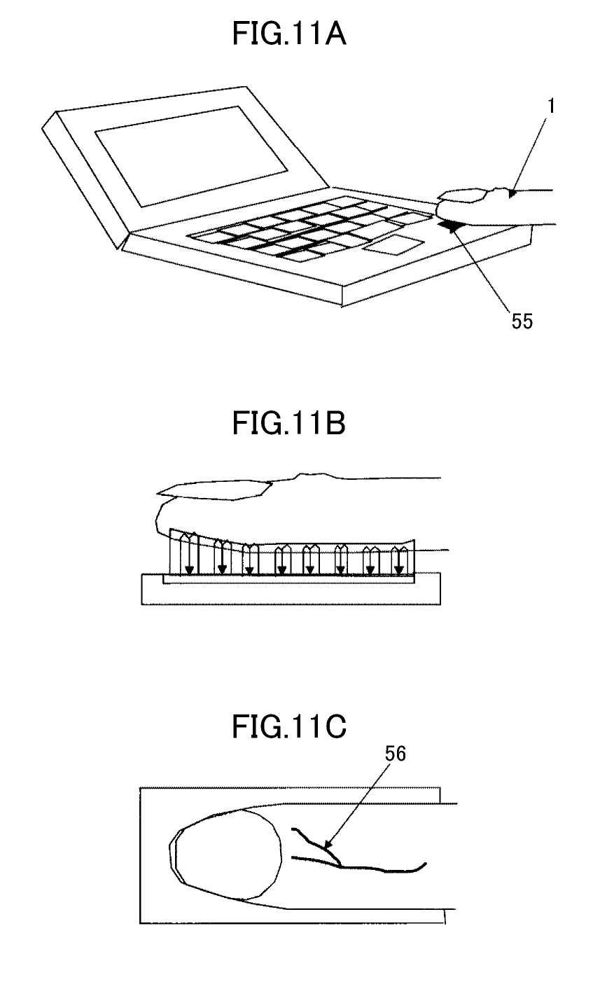

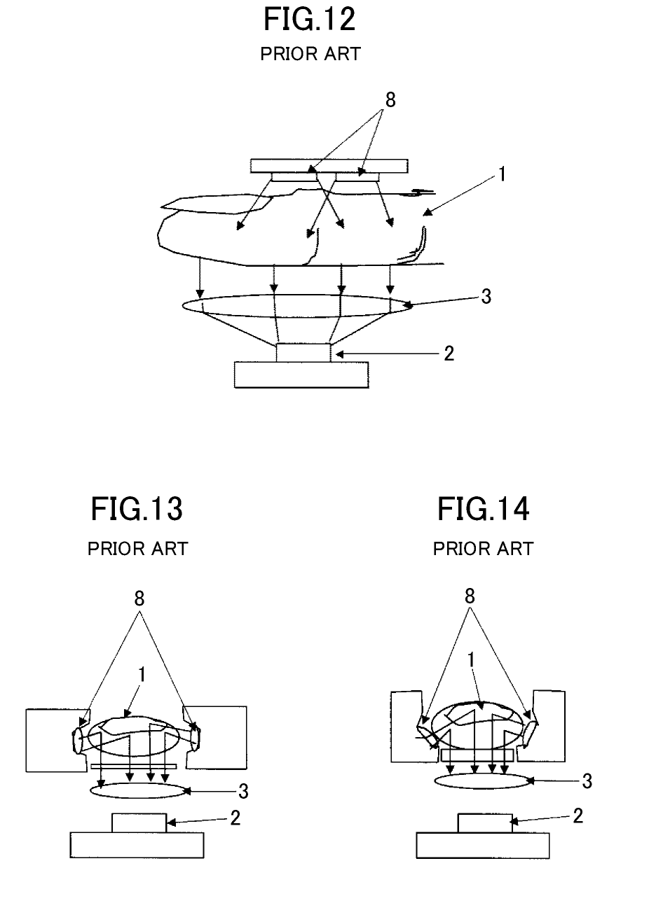

FIGS. 11A to 11C are views showing a use example of the photosensor of the embodiment. As shown in FIG. 11A, the photosensor of the embodiment is incorporated as a vein authentication sensor 55 of a vein authentication apparatus into a notebook computer.

As shown in FIG. 11B, the backlight (B/L) arranged below the photosensor array 2 irradiates infrared light to the hand or the finger 1, and as shown in FIG. 11C, the surface of or a vein 56 existing slightly inside the hand or the finger 1 is imaged onto the photosensor array 2.

As is apparent from FIG. 11A, since the vein sensor 55 is provided in the keyboard portion of the notebook computer, the vein sensor is required to be compact. Since the vein sensor 55 of the embodiment has such a structure that the backlight (B/L) having the infrared light LED is arranged on the back surface of the photosensor array 2, the vein sensor can be designed to be thin and can be made compact.

On the other hand, in the related art photosensor array, since a CCD or a MOS is used as a photosensor pixel, irradiation from the back surface is impossible. Besides, since a lens is required, a specific distance is required between the infrared light source and the hand or the finger, or between the hand or the finger and the lens. By these factors, the photosensor using the related art photosensor array can not be made compact.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A photosensor comprising:
a photosensor array in which a plurality of photosensor pixels are arranged in a matrix form; and
a backlight arranged below the photosensor array, wherein
the photosensor array includes a surface light-shielding film, and
the surface light-shielding film includes an incident hole through which light from an opposite side to the backlight is incident on the respective photosensor pixels, and a passage hole which is provided around the incident hole and irradiates the opposite side with irradiation light from the backlight.

2. The photosensor according to claim 1, wherein the backlight includes a light guide plate and a light source arranged on a side surface of the light guide plate.

3. The photosensor according to claim 2, further comprising a reflecting film arranged on a surface of the light guide plate at an opposite side to the photosensor array.

4. The photosensor according to claim 2, further comprising a plurality of optical sheets arranged on a surface of the light guide plate at a side of the photosensor array.

5. The photosensor according to claim 1, wherein the backlight includes a light guide plate and a light source arranged on a surface of the light guide plate at an opposite side to the photosensor array.

6. The photosensor according to claim 5, further comprising a plurality of optical sheets arranged on a surface of the light guide plate at a side of the photosensor array.

7. The photosensor according to claim 1, wherein each of the photosensor pixels includes a lower electrode made of a metal film, an amorphous silicon film provided on the lower electrode, an n-type amorphous silicon film provided on the amorphous silicon film, and an upper electrode provided on the n-type amorphous silicon film.

8. The photosensor according to claim 7, further comprising a flattening film provided between the respective photosensor pixels.

9. The photosensor according to claim 8, wherein the flattening film is an organic insulating film.

10. The photosensor according to claim 8, wherein
the surface light-shielding film is arranged between the flattening film and the upper electrode, and
a passage hole for irradiating the opposite side with the light from the backlight is formed also in the lower electrode at a place corresponding to the passage hole of the surface light-shielding film.

11. The photosensor according to claim 7, further comprising an insulating film provided between the lower electrode and the amorphous silicon film, wherein
the insulating film includes a hole in an area corresponding to each of the photosensor pixels, and
the lower electrode and the amorphous silicon film are electrically connected to each other in the hole formed in the insulating film.

12. The photosensor according to claim 7, wherein the lower electrode is formed on a transparent substrate.

13. The photosensor according to claim 7, further comprising a surface protecting layer provided on the upper electrode.

14. The photosensor according to claim 7, wherein
the upper electrode is made of ITO, and
the surface light-shielding film is made of Al.
